(19) United States
(12) Patent Application Publication
(10) Pub. No.: US 2023/0051861 A1
(43) Pub. Date: Feb. 16, 2023

(54) SIZEABLE CONDUITS

(71) Applicant: Hewlett-Packard Development Company, L.P., Spring, TX (US)

(72) Inventors: Sheng-Lung Liao, Taipei City (TW); Chien Fa Huang, Taipei City (TW)

(73) Assignee: Hewlett-Packard Development Company, L.P., Spring, TX (US)

(21) Appl. No.: 17/793,661

(22) PCT Filed: Feb. 14, 2020
(86) PCT No.: PCT/US2020/018401

§ 371 Date: Jul. 19, 2022

(51) Int. Cl. H05K 7/20; G06F 1/20

(52) U.S. Cl. CPC H05K 7/20272; G06F 1/20

(57) ABSTRACT

According to an example, a conduit sizeable in length and width comprises a first cover and a second cover. The first cover comprises a first interfacing area between a first component and a second component. The second cover comprises a second interfacing area between a third component and a fourth component. The first cover and the second cover comprise a third interfacing area.

### BACKGROUND

Computers may use conduits to conduct liquids, gases or finely divided solids between two locations within their inner volume. Due to the different computer configurations, sizeable conduits may be used to adapt the conduit dimensions to the computer. Those sizeable conduits comprise a range of operable sizes for their passageways. It is hereby disclosed conduit systems and sizeable conduits for computers in which the dimensions can be modified so that the dimensional specifications are accomplished.

### BRIEF DESCRIPTION OF DRAWINGS

Features of the present disclosure are illustrated by way of example and are not limited in the following figure(s), in which like numerals indicate like elements, in which:

FIG. 1 shows a sizeable conduit comprising lateral slits, according to an example of the present disclosure;

FIG. 2 shows a sizeable conduit comprising upper and lateral slits, according to an example of the present disclosure:

FIG. 3 shows a sizeable conduit having different types of slits, according to an example of the present disclosure;

FIG. 4 shows a sizeable duct comprising a series of slits, according to an example of the present disclosure;

FIG. 5 shows a top view of a sizeable conduit in a disengaged state, according to an example of the present disclosure;

FIG. 6 shows the sizeable conduit of FIG. 5 in an engaged state;

FIG. 7 shows a lateral view of a sizeable conduit in a disengaged state, according to an example of the present disclosure:

FIG. 8 shows the sizeable conduit of FIG. 7 in an engaged state;

FIG. 9 shows a duct system sizeable in width, length, and height, according to an example of the present disclosure.

### DETAILED DESCRIPTION

For simplicity and illustrative purposes, the present disclosure is described by referring mainly to examples. In the following description, numerous specific details are set forth in order to provide a thorough understanding of the present disclosure. It will be readily apparent, however, that the present disclosure may be practiced without limitation to these specific details. In other instances, some methods and structures have not been described in detail so as not to unnecessarily obscure the present disclosure.

Throughout the present disclosure, the terms “a” and “an” are intended to denote at least one of a particular element. As used herein, the term “includes” means includes but not limited to, the term “including” means including but not limited to. The term “based on” means based at least in part on.

Disclosed herein are examples of devices and systems which may be sizeable in different dimensions. Hence, different examples of devices and systems are described.

Desktop computers and all-in-one computers comprise computer cases to contain hardware components, Among other things, factors that determine the size and the shape of computer cases are the number and the size of hardware components contained within their inner volume. During operation, some of the hardware components may produce heat which may increase the computer case inner volume temperature. Since having an inner volume temperature over a permissible temperature limit may cause temporary malfunction or permanent failure, cooling systems and devices are used. Those cooling system and devices enable to remove the waste heat produced by hardware components, Hardware components susceptible to overheating include, among others, integrated circuits such as central processing units (CPUs), chipsets, graphic cards, and storage drives.

Cooling may be designed to reduce the ambient temperature within the inner volume of the computer case, such as by exhausting hot air, cooling a hardware component or cooling a small area.

According to an example, hardware components may be cooled by an airflow conducted from an exterior region of the computer case. The airflow may be inserted into the inner volume through a fan, wherein an outlet side of the fan is facing the inner volume of the computer. The airflow may be conducted to the hardware component or area by a conduit so that the temperatures rise produced by a given amount of heat can be reduced. However, in other examples, the conduit may be replaced by a cover facing an inner surface of the computer case so that a passageway is defined for the airflow.

Throughout this description, the term “conduit” refers generally to a structural element capable of conducting a liquid, a gas or a finely divided solid through a passage. Examples of conduits comprise covers, ducts and any kind of structure able to define passages, Covers may be used along other elements to define passages, such as hardware components or inner surfaces of computer cases.

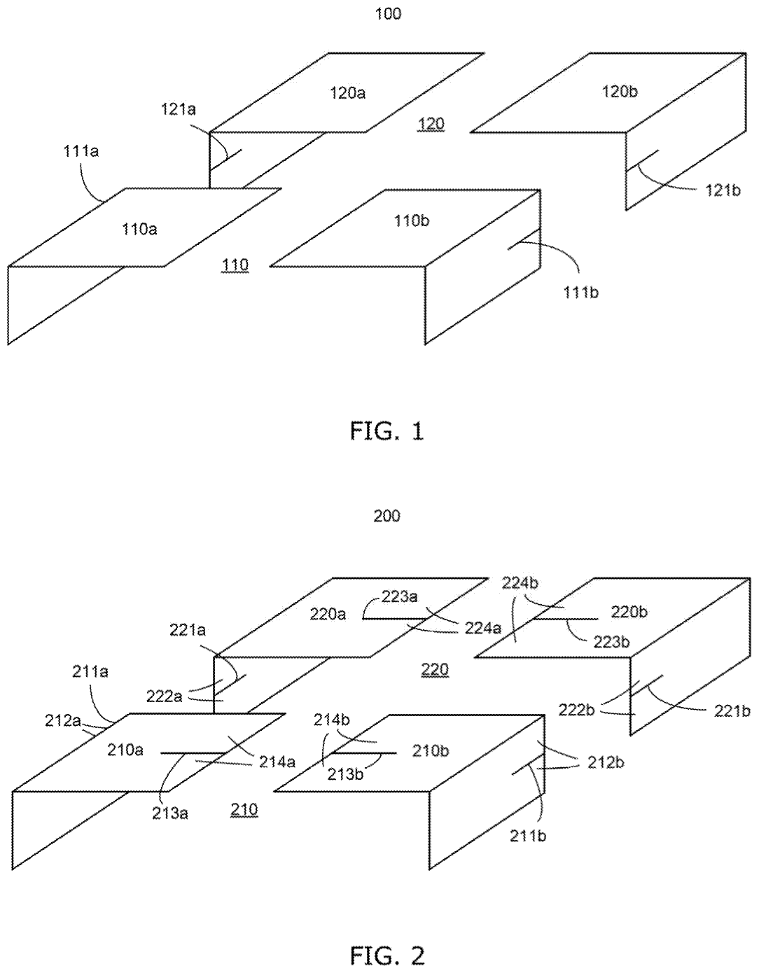

Referring now to FIG. 1, a sizeable conduit 100 comprising a first cover 110 and a second cover 120 is shown. The first cover 110 and the second cover 120 can be interconnected so that the sizeable conduit 100 is sizeable in length and width. The first cover 110 is sizeable in width and comprises a first component 110a and a second component 110b, Both components overlap in a first overlapping area (not shown in FIG. 1), The second cover 120 is sizeable in width and comprises a third component 120a and a fourth component 120b. The third component 120a and the fourth component 120b overlap in a second overlapping area (not shown in FIG. 1). A movement of the first component 110a relative to the second component 110b adjusts a first cover width. A movement of the third component 120a relative to the fourth component 120b adjusts a second cover width. In order to define a hermetic conduit, the first cover 110 and the second cover 120 have the same width. The first cover 110 and the second cover 120, in use, are overlapping in a third overlapping area (not shown in FIG. 1). The overlap allows adjusting a length of the sizeable conduit by changing the third overlapping area, i.e. a movement of the first cover 110 relative to the second cover 120 changes the sizeable conduit length. When the components of the sizeable conduit 100 are interconnected, a series of overlaps between the components are generated. The overlaps may enable the sizeable conduit to be adjustable in width and length. In other examples, the sizeable conduit 100 may be defined as capable of being telescopic in width and length.

In some examples, when the first component 110a and the second component 110b are interconnected, the first component 110a and the second component 110b have an overlap. The overlap may be referred to as a first interfacing area, and thereby, the first component 11a and the second component 110b have the first interfacing area (not shown in FIG. 1). When the third component 120a and the fourth component 120b are interconnected, the third component 120a and the fourth component 120b have an overlap. The overlap may be referred to as a second interfacing area, and thereby, the third component 120a and the fourth component 120b have the second interfacing area (not shown in FIG. 1).

In some other examples, when the first cover 110 and the second cover 120 are interconnected, the first cover 110 and the second cover 120 have an overlap. The overlap may be referred as a third interfacing area, and thereby, the first cover 110 and the second cover 120 have the third interfacing area (not shown in FIG. 1).

In the example of FIG. 1, the first component 110a, the second component 110b, the third component 120a, and the fourth component 120b comprise a first series of lateral slits 111a, a second series of lateral slits 111b, a third series of lateral slits 121a, and a fourth set of lateral slits 121b, respectively. However, in other examples, the components may not comprise the slits.

In FIG. 1, the series of slits enable the corresponding components to be interconnected through their slits. The first component 110a is the corresponding component of the third component 120a and the second component 110b is the corresponding component of the fourth component 120b. Therefore, the first series of lateral slits 111a is corresponding to the third series of lateral slits 121a and the third series of lateral slits 111b is corresponding to the third series of lateral slits 121b. The slits' usage enables the sizeable conduit to be more hermetic than a sizeable conduit without slits. However, in other examples, the sizeable conduit 100 does not comprise the lateral slits and the first cover 110 overlaps the second cover 120.

In other examples, the sizeable conduit 100 may be used to conduct a substance (such as a liquid, a gas or finely divided solids) between an inlet side and an outlet side. The sizeable conduit 100 may be used along with a hardware component or an inner surface of a computer case so that to define a closed passage.

Referring now to FIG. 2, a sizeable conduit 200 comprising upper and lateral slits is shown. The sizeable conduit 200 is sizeable in width and length and comprises a first cover 210 and a second cover 220. The first cover 210 can overlap the second cover 220 so that a sizeable conduit length can be changed. The first cover 210 comprises a first component 210a and a second component 210b. The second cover 220 comprises a third component 220a and a fourth component 220b. The first cover 210 is connected to the second cover 220 by the lateral slits, as previously explained in relative to FIG. 1. A first slit 211a and a second slit 211b are corresponding slits and a third slit 221a and a fourth slit 221b are corresponding slits. In other examples, the number of slits and/or their locations may be different.

In addition to the lateral slits, the first component 210a comprises a first upper slit 213a, the second component 210b comprises a second upper slit 213b, the third component 220a comprises a third upper slit 223a, and the fourth component 220b comprises a fourth upper slit 223b. Although in FIG. 2 the slits are distributed at the upper faces and the lateral faces, in other examples the slits may be comprised in other configurations which enable interconnection between the first cover 210, the second cover 220 and their components.

According to the example of FIG. 2, the slits of the sizeable conduit 200 define sets of consecutive flanges. As used herein, flanges may be understood as projecting edges of a component resulting from the presence of the slits within a face of the component.

For instance, in the first component 210a, the first slit 211a defines a first set of flanges 212a and the first upper slit 213a defines a second series of flanges 214a. In the second component 210b, the second slit 211b defines a third set of flanges 212b and the second upper slit 213b defines a fourth set of flanges 214b. Accordingly, in the third component 220a and the fourth component 220b are defined a fifth set of flanges 222a, a sixth set of flanges 224a, a seventh set of flanges 222b, and an eighth set of flanges 224b.

In the example of FIG. 2, the upper slits and the lateral slits are orthogonal to the edges of their respective component. However, in other examples, the slits may be oblique relative to the edges of their respective component.

In some examples, when the first component 210a and the second component 210b are interconnected, the first component 201a and the second component 210b have an overlap referred to as a first interfacing area. As a consequence, the first component 210a and the second component 210b have the first interfacing area (not shown in FIG. 2). Accordingly, when the third component 220a and the fourth component 220b are interconnected, the first component 201a and the second component 210b have an overlap referred to as a second interfacing area. As a consequence, the third component 210a and the fourth component 210b have the third interfacing area (not shown in FIG. 2). In other examples, the first interfacing area and the second interfacing area are generated in use, i.e. when the components of the sizeable conduit 200 are engaged.

In some other examples, when the first cover 210 and the second cover 120 are interconnected, the first cover 210 and the second cover 220 have an overlap. The overlap may be referred as a third interfacing area, and thereby, the first cover 210 and the second cover 220 have the third interfacing area (not shown in FIG. 2). A length of the sizeable conduit 200 can be modified by changing a length dimension of the third interfacing area.

The interfacing areas may be located at opposite faces of the components, since the first component 210a may intersect the second component 210b and the third component 220a may intersect the fourth component 220b. A width of the sizeable conduit 200 is changed as the first cover 210 and the second cover 220 move with respect to each other.

According to some examples, the consecutive flanges of each of the first component 210a, second component 210b, third component 220a, and the fourth component 220b contact consecutive opposite faces of their corresponding component.

In other examples, a sizeable conduit may comprise different flanges geometries in its components. As used herein, flange geometry refers to the size and/or shape of the flanges resulting from the series of slits. In the example of FIG. 2, the series of flanges comprise a common flange geometry, i.e., dividing the total length of the edge into two equal lengths. However, in other examples a first flange geometry, a second flange geometry and a third flange geometry may be possible. The first flange geometry may enable to interconnect the first component with the second component. The second flange geometry may enable to interconnect the third component with the fourth component. The third flange geometry may enable to interconnect the first cover with the second cover. In some examples, the first flange geometry and the second flange geometry may be the same, i.e. the shape and/or size of the flanges may be the same.

Throughout this description, the term “flanges” refers generally to projecting elements of a face of a component resulting from the presence of slits within the face of the component. Series of consecutive flanges may be defined by series of slits.

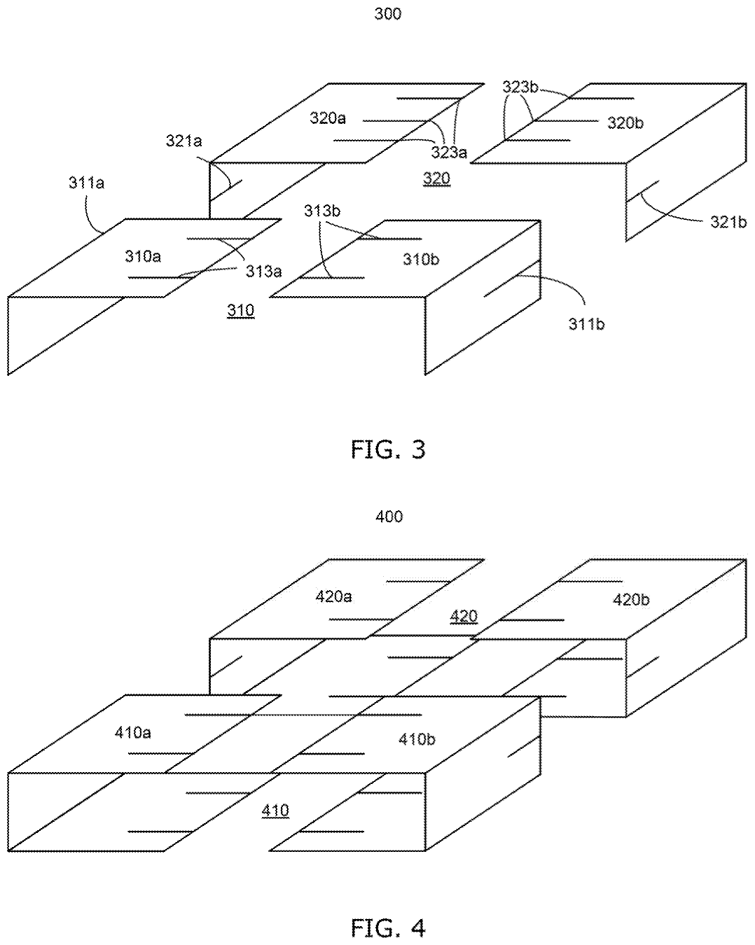

Referring now to FIG. 3, a sizeable conduit 300 comprising a first cover 310 and a second cover 320 is shown. The first cover 310 comprises a first component 310a and a second component 310b. The second cover 320 components can be interconnected through a first set of slits 313a and a second set of slits 313b, wherein the slits are orthogonal to their respective component edge. The second cover 320 comprises a third component 320a and a fourth component 320b, wherein the third component 320a comprises a third set of slits 323a and the fourth component 320 comprises a fourth set of slits 323b. The third set of slits 323a and the fourth set of slits 323b are different relative to the first set of slits 313a and the second set of slits 313b. The sets of layers define a width range for each of the first cover 310 and the second cover 320 so that a sizeable conduit width is configured.

As described in the above examples, the sizeable conduit 300 comprises a first interfacing area within the first cover 310, a second interfacing area within the second cover 320, and a third interfacing area between the first cover 310 and the second cover 320.

In the example of FIG. 3 the first cover 310 is connected to the second cover 320 by lateral slits. However, in other examples, the slits may be positioned at a different location so that the sizeable conduit 300 is telescopic. The first component 311a comprises a first set of lateral slits 311a, the second component 310b comprises a second set of lateral slits 311b, the third component 320a comprises a third set of lateral slits 321a, and the fourth component 320b comprises a fourth set of lateral slits 321b. In FIG. 3, the lateral slits comprised in the first and the second set are having a greater length relative to the lateral slits comprised in the third and the fourth set. However, in other examples, the slits may be equal or may have a different orientation, for instance, oblique relative to the components' edges.

According to the examples of FIGS. 1 to 3, the first cover components and the second cover components comprise an L-shaped profile. However, in other examples, the components may comprise different profiles so that covers are defined. In some examples, the first cover and the second cover may have different dimensions, i.e. different lengths and/or widths.

In some examples, the sizeable conduits previously described are used within a computing system. The computing system may comprise a fan, a sizeable conduit, and a hardware component, wherein the fan introduces an airflow from an exterior region of the computing system. The sizeable conduit may comprise dimensions that enable connecting the fan with the hardware component. The sizeable conduit may conduct the airflow to the hardware component so that a hardware component temperature is reduced. The sizeable conduit may be used along other elements to define a passage, such as the hardware component, an inner surface of the computing system or both. The passage may comprise a quadrilateral shape, however, other alternatives are possible, for instance, a quadrilateral shape.

Referring now to FIG. 4, a sizeable duct 400 is shown. The sizeable duct 400 comprises a series of channels interconnected by a series of slits so that a width and a length of the duct can be modified. As previously explained in the description, the sizeable duct 400 may be used within a computer for cooling purposes. The sizeable duct 400 comprises a first portion 410 and a second portion 420. The first portion 410 and the second portion 420 may be alternatively referred to as first duct and second duct, respectively. The first portion 410 comprises a first component 410a and a second component 410b, wherein the first component 410a and the second component 410b can be interconnected through a series of upper and lower slits. In some examples, a passage defined by the first portion 410 and the second portion 420 comprises a quadrilateral shape. The overlap between the first component 410a and the second component 410b can be referred to as a first interfacing area. The second portion 420 comprises a third component 420a and a fourth component 420b, wherein the third component 420a and the fourth component 420b can be interconnected through a series of upper and lower slits. The overlap between the third component 420a and the fourth component 420b can be referred to as a second interfacing area.

The first portion 410 and the second portion 420, in use, are interconnected through a series of lateral slits, wherein an interconnection defines a third interfacing area, Upon interconnecting the components of the sizeable duct 400, a passage comprising a quadrilateral shape is defined. However, in other examples, the components may comprise other profiles that may define a parallelogram shape, for instance. In FIG. 4 the lateral slits are having the same length however, in other examples, the slits comprised in the first and the second components may have different lengths relative to the third and the fourth components.

According to some examples, a sizeable duct may comprise a first portion 410 having a first and a second component having a C-shaped profile and a second portion comprising a different profile. In an example, the second portion 420 may comprise a third component and a fourth component having an L-shaped profile, as described by FIGS. 1 to 3. Having a cover in the second portion may enable to improve the cooling of a hardware component by redirecting an airflow. Alternatively, the sizeable ducts may be referred to as adjustable air ducts.

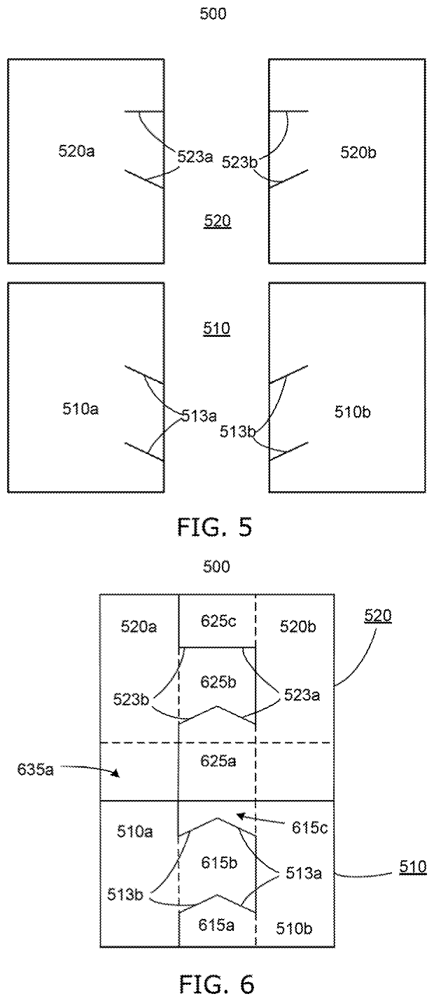

Referring now to FIG. 5, a top view of a sizeable duct 500 in a diseangaged state is shown. The sizeable duct 500 comprises a first duct 510 and a second duct 520. The first duct 510 comprises a first component 510a and a second component 510b and the second duct 520 comprises a third component 520a and a fourth component 520b. Each component comprises a series of linear slits that enable interconnecting a component with its complementary component. For instance, the first component 510a has as a complementary component the second component 510b. Accordingly, the third component 520a has as a complementary component the fourth component 520b.

Components are interconnected to their corresponding components via sets of corresponding slits. The first component 510a and the second component 510b are interconnected via a first set of corresponding slits of the series of linear slits. The first set of corresponding slits comprises the first component slits 513a and the second component slits 513b. Accordingly, the third component 520a and the fourth component 520b are interconnected via a second set of corresponding slits of the series of linear slits. The second set of corresponding slits comprises the third component slits 523a and the fourth component slits 523b. The sizeable duct 500 is sizeable in length and width, as previously explained examples.

Referring now to FIG. 6, a second top view of the sizeable duct 500 in an engaged state is shown. The sizeable duct components are interconnected, and therefore, interfacing areas are defined. The linear slits within a component define a series of component flanges, wherein the component of flanges intersect their corresponding component flanges. In the example of FIG. 6, consecutive flanges of each of the first component 510a, the second component 510b, the third component 520a and the fourth component 520b contact consecutive opposite faces of their corresponding component.

The first component 510a and the second component 520b are overlapping in a first interfacing area, wherein the first interfacing area comprises a first overlap 615a, a second overlap 615b, and a third overlap 615c. In the first overlap 615a, a first flange of the first component is positioned over a first flange of the second component. In the second overlap 615b, a second flange of the first component is positioned under a second flange of the second component. In the third overlap 615c, a third flange of the first component is positioned over a third flange of the second component.

The third component 520a and the fourth component 520b are overlapping in a second interfacing area, wherein the second interfacing area comprises a fourth overlap 625a, a fifth overlap 625b, and a sixth overlap 625c. As explained above, consecutive flanges of a component contact consecutive opposite faces of its corresponding component.

The first duct 510 and the second duct 520 are overlapping in a third interfacing area. The third interfacing area comprises an eight overlap 635a and lateral overlaps (not shown in FIG. 6). When adjusting the length of the sizeable duct 500 while maintaining a width of the first duct 510 and the second duct 520, the third interfacing area is changed. When increasing the length of the sizeable duct 500, the third interfacing area is reduced.

In the example of FIG. 6, the first interfacing area is equal to the second interfacing area. However, in other examples, the components of the second duct 520 may have different dimensions relative to the components of the first duct 510, and therefore, the first and the second interfacing areas when being connected can be different. In an example, the second duct 520 may have a larger length relative to the first duct 510.

In the examples of FIG. 5 and FIG. 6, the flanges comprised in the first duct 510 are different from the flanges of the second duct 520. As previously described in the description, within a same sizeable duct, different flanges geometries may be possible. In the example of FIG. 5 and FIG. 6, the first component slits 513a and the second component slits 513b are having a first flange geometry and the third component slits 523a and the fourth component slits 523b are having a second flange geometry. In other examples, components may have a common flange geometry to interconnect the corresponding components.

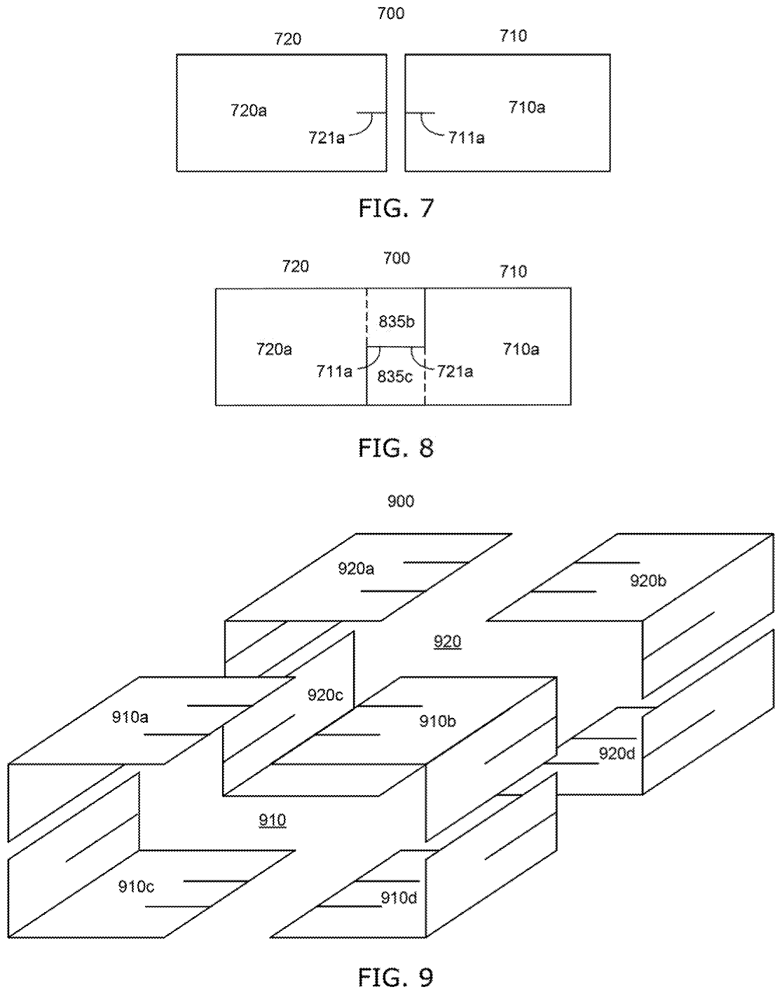

Referring now to FIG. 7, a left-side view of a sizeable duct 700 in a disengaged state is shown. The sizeable duct 700 comprises a first duct 710 and a second duct 720, The lateral view of the sizeable duct 700 may correspond to the sizeable duct of FIG. 5 and FIG. 6, The first duct 710 comprises a first component 710a and the second duct 720 comprises a third component 720a. The first duct 710 may be interconnected to the second duct 720 via a third set of corresponding slits, wherein the third set comprises a first linear slit 711a and a third linear slit 721a.

In the example of FIG. 7, the linear slits are having the same dimensions, however, in other examples the slits may be different, e.g., having different dimensions and/or orientations.

Referring now to FIG. 8, a second left-side view of the sizeable duct 700 in an engaged state is shown. The interconnection between the series of components comprised in the sizeable duct 700 causes a series of interfacing areas. The first duct 710 and the second duct 720 overlap in a third interfacing area. The third interfacing area comprises a ninth overlap 835b, a tenth overlap 835c, and the remaining overlaps not visible in FIG. 8. When adjusting the length of the sizeable duct 700 while maintaining a width of the first duct 710 and the second duct 720, the third interfacing area is changed. When increasing the length of the sizeable duct 700, the third interfacing area is reduced.

In the examples of FIG. 7 and FIG. 8, the lateral flanges comprised in the first duct 710 are the same as the lateral flanges of the second duct 720. However, as previously described in the description, within a same sizeable duct, different flanges geometries may be possible. The flange geometries of the first duct 710 and the second duct 720 may be referred to as a third flange geometry. The first flange geometry and the second flange geometry may correspond to the resultant geometries of each of the first set of corresponding slits and the second set of corresponding slits, respectively. Accordingly, the third flange geometry may correspond to the third set of corresponding slits.

In other examples, the sizeable ducts from FIGS. 5 to 8 may be referred to as adjustable air ducts. In some examples, the sizeable ducts examples from FIGS. 5 to 8 may be replaced for sizeable conduits. Sizeable conduits may correspond to one of the previously described examples in reference to FIGS. 1 to 3.

According to some other examples, the sizeable ducts may comprise a duct and a cover, wherein the duct may be the first duct 410 previously in reference to FIG. 4, and the cover may be the cover 120, 220 and 320 previously explained in reference to FIGS. 1 to 3.

Referring now to FIG. 9, a duct system 900 adjustable in width, height and length is shown. The duct system 900 comprises a series of elements to define a conduit between an inlet and an outlet. The duct system 900 may be used along other elements to cool hardware components. In an example, the duct system may be used within a computing system to define a passage for an airflow generated by a fan. The duct system 900 comprises a first portion 910 and a second portion 920, wherein the portions comprise a series of sub-elements to define the duct.

The first portion 910 comprises a first upper element and a first lower element, wherein the elements comprise a series of interconnectable components. The first upper element comprises a first component 910a and a second component 910b and the first lower element comprises a third component 910c and a fourth component 910d.

The second portion 920 comprises a second upper element and a second lower element, wherein the elements are interconnectable with each other and with the elements comprised in the first portion 910. The second upper element comprises a fifth component 920a and a sixth component 920b and the second lower element comprises a seventh component 920c and an eighth component 920d.

According to some examples, the components of the first portion 910 and the second portion 920 comprise a series of flanges and the components are interconnected via corresponding flanges.

As previously described in reference to FIGS. 1 to 8, the components of the duct system 900 comprise a series of linear slits. The series of slits enable corresponding elements to be interconnected through a series of consecutive flanges. The overlaps between the components allow to set a width, a height and a length. However, in other examples, the duct system may not comprise slits in its components, as previous examples of the description.

In the example of FIG. 9, the duct system 900 comprises a series of overlapping areas when the components are interconnected. In the first upper element of the first portion 910, the first element 910a and the second element 910b are overlapping in a first overlapping area. In the first lower element of the first portion 910, the third component 910c and the fourth component 910d are overlapping in a second overlapping area. In the second upper element of the second portion 920, the fifth element 920a and the sixth element 920b are overlapping in a third overlapping area. In the second lower element of the second portion 920, the seventh component 920c and the eighth component 920d are overlapping in a fourth overlapping area. Within the first portion 910, the first upper element and the first lower element overlap in a fifth overlapping area. Within the second portion 920, the second upper element and the second lower element overlap in a sixth overlapping area. The fifth and the sixth overlapping areas enable to adjust a height for the duct system 900. The first portion 910 and the second portion 920 overlap in a seventh overlapping area. A movement of the first portion 910 relative to the second portion 920 enables to adjust the length of the duct system 900. As previously described, the first portion 910 and the second portion 920 can set the width of the duct system 900.

In other examples, when the components of the duct system 900 are interconnected further areas are defined. The first component 910a, the third component 910c, the fifth component 920a and the seventh component 920c overlap in a first shared area. The second component 910b, the fourth component 910d, the sixth component 920b, and the eighth component 920d overlap in a second shared area.

According to some examples, a passage defined by a first portion and a second portion of a duct system comprises a quadrilateral shape. However, other alternative shapes for the passage may be possible, for instance, a parallelogram shape.

According to some other examples, a computing system comprises a fan comprising an outlet side and an adjustable air duct. The adjustable air duct may correspond to one of the previously explained examples, for instance, a sizeable conduit, a sizeable duct, a duct system, or a combination thereof. The fan may produce an airflow towards the adjustable air duct so that the airflow moves from the inlet side of the adjustable air duct to an outlet side of the adjustable air duct through a passage. In some examples, the passage defined by the adjustable air comprises a quadrilateral shape. The airflow may be used to cool a hardware component. The adjustable air duct may be positioned so that it faces the outlet side of the fan, By connecting the outlet side of the fan to the adjustable air duct, the airflow may be moved towards the hardware component, thereby cooling it.

In other examples, the outlet side of the fan is contacting the inlet side of the adjustable air duct, A passage defined by the adjustable air duct may have dimensions which partially span a diameter of the fan so that a maximum amount of airflow is conducted towards a hardware component. In some examples, the adjustable air duct may be sizeable in width and length, however, other examples may comprise an adjustable air duct sizeable in width, length, and height.

What has been described and illustrated herein are examples of the disclosure along with some variations. The terms, descriptions, and figures used herein are set forth by way of illustration only and are not meant as limitations, Many variations are possible within the scope of the disclosure, which is intended to be defined by the following claims (and their equivalents) in which all terms are meant in their broadest reasonable sense unless otherwise indicated.

1. A sizeable conduit comprising:
a first cover sizeable in width, wherein the first cover comprises a first interfacing area between a first component and a second component, and;
a second cover sizeable in width, wherein the second cover comprises a second interfacing area between a third component and a fourth component,
wherein the first cover and the second cover have a third interfacing area,
wherein the sizeable conduit is sizeable in length and width.

2. A sizeable conduit as claimed in claim 1, wherein the first component, the second component, the third component, and the fourth component comprise a series of linear slits.

3. A sizeable conduit as claimed in claim 2, wherein the slits are oblique with respect to their corresponding edges.

4. A sizeable conduit as claimed in claim 2, wherein the first component is interconnected with the second component via a first set of corresponding slits of the series of linear slits and the third component is interconnected with the fourth component via a second set of corresponding slits of the series of linear slits.

5. A sizeable conduit as claimed in claim 4, wherein the first cover is interconnected with the second cover via a third set of corresponding slits of the series of linear slits.

6. A computing system comprising:
a fan comprising an outlet side, and;
an adjustable air duct comprising:
a first duct comprising a first component and a second component overlapping in a first interfacing area, and;
a second duct comprising a third component and a fourth component overlapping in a second interfacing area,
wherein a width of the first duct and the second duct is adjustable,
wherein the first duct and the second duct are overlapping in a third interfacing area so that a length is adjustable,
wherein an outlet side of the fan is connected to the adjustable air duct.

7. A computing system as claimed in claim 6, wherein the first component, the second component, the third component and the fourth component comprise a series of flanges.

8. A computing system as claimed in claim 7, wherein the flanges of the first component and the second component and the flanges of the third and fourth component are corresponding so that to interconnect at a desired width.

9. A computing system as claimed in claim 6, wherein the length of the adjustable air duct is increased when a length of the third area is decreased.

10. A computing system as claimed in claim 7, wherein the series of flanges of the adjustable air duct comprise:
a first flange geometry to interconnect the first component with the second component and the third component with the fourth component; and,
a second flange geometry to interconnect the first duct with the second duct, wherein the first flange geometry is different from the second flange geometry.

11. A computing system as claimed in claim 6, wherein the adjustable air duct defines a passage, wherein the passage comprises a quadrilateral shape.

12. A computing system as claimed in claim 7, wherein consecutive flanges of each of the first component, the second component, the third component and fourth component contact consecutive opposite faces of their corresponding component.

13. A duct system comprising:
a first portion comprising:
a first upper element comprising a first component and a second component, wherein the first element and the second element are overlapping;
a first lower element comprising a third component and a fourth component, wherein the third component and the fourth component are overlapping; and,
a second portion,
a second upper element comprising a fifth component and a sixth component, wherein the fifth component and the sixth component are overlapping;
a second lower element comprising a seventh component and an eighth component, wherein the seventh component and the eight component are overlapping,
wherein the first component, the third component, the fifth component and the seventh component overlap in a first area and the second component, the fourth component, the sixth component, and the eighth component overlap in a second area,
wherein the duct system is adjustable in width, height and length.

14. A duct system as claimed in claim 13, wherein the components comprise a series of flanges, wherein the components are interconnected via corresponding flanges.

15. A duct system as claimed in claim 13, wherein a passage defined the first portion and the second portion comprise a quadrilateral shape.
